(19) United States
(12) Patent Application Publication
(10) Pub. No.: US 2009/0142702 A1
(43) Pub. Date: Jun. 4, 2009

(54) METHODS OF USING VIOLET-SENSITIVE IMAGEABLE ELEMENTS

(76) Inventors: Kevin B. Ray, Fort Collins, CO (US); Ting Tao, Fort Collins, CO (US); Eric E. Clark, Loveland, CO (US)

Correspondence Address: Andrew J. Anderson;Patent Legal Staff, Eastman Kodak Company, 343 State Street, Rochester, NY, 14650-2201, US

(21) Appl. No.: 11/949,817

(22) Filed: Dec. 4, 2007

(51) Int. Cl. G03F 7/028; G03C 5/29

(52) U.S. Cl. 430/302; 430/328

(57) ABSTRACT

An imaged and developed element, such as a lithographic printing plate, is provided by violet radiation imaging of a negative-working imageable element having an outermost imageable layer that includes a free radically polymerizable component, an initiator composition that provides free radicals upon violet irradiation, a sensitizer, and a polymeric binder having pendant reactive vinyl groups. The element also includes an additive that is represented by the following Structure (II):

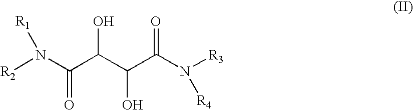

wherein R₁, R₂, R₃, and R₄ are independently hydrogen, or alkyl, alkenyl, cycloalkyl, or aryl groups. The imaged element can be developed using a gum having a pH greater than 6 and up to about 11 and comprising at least 1 weight % of one or more anionic surfactants.

### FIELD OF THE INVENTION

This invention relates to a method of imaging and processing violet-sensitive negative-working imageable elements such as negative-working lithographic printing plate precursors. The invention uses certain gums for processing instead of the usual alkaline developers.

### BACKGROUND OF THE INVENTION

Radiation-sensitive compositions are routinely used in the preparation of imageable materials including lithographic printing plate precursors. Such compositions generally include a radiation-sensitive component, an initiator system, a sensitizing compound, and a binder, each of which has been the focus of research to provide various improvements in physical properties, imaging performance, and image characteristics. Sometimes other additives are included to provide desired properties.

Recent developments in the field of printing plate precursors concern the use of radiation-sensitive compositions that can be imaged by means of lasers or laser diodes. Laser exposure does not require conventional silver halide graphic arts films as intermediate information carriers (or “masks”) since the lasers can be controlled directly by computers. High-performance lasers or laser-diodes that are used in commercially-available image-setters are designed to emit radiation at a desired wavelength to which the precursors are sensitive, for example a wavelength of at least 350 nm, and thus the radiation-sensitive compositions are required to have spectral sensitivity of at least 350 nm in the electromagnetic spectrum.

There are two possible ways of using radiation-sensitive compositions for the preparation of printing plates. For negative-working printing plates, exposed regions in the radiation-sensitive compositions are hardened to provide an image and unexposed regions are removed during development. For positive-working printing plates, the exposed regions are removed and the unexposed regions provide an image.

Various radiation-sensitive compositions and imageable elements are described in U.S. Pat. Nos. 6,309,792 (Hauck et al.), 6,893,797 (Munnelly et al.), 6,787,281 (Tao et al.), and 6,899,994 (Huang et al.), U.S. Patent Application Publication 2003/0118939 (West et al.), and EP 1,079,276A1 (Lifka et al.) and EP 1,449,650A1 (Goto). Other negative-working imageable elements are described, for example, in U.S. Pat. Nos. 6,916,595 (Fujimaki et al.), 6,702,437 (Fujimaki et al.), and 6,727,044 (Fujimaki et al.), Japanese Kokai 2000-187322 (Mitsubishi Chemical Co.), and U.S. Patent Application Publications 2004/0131972 (Fujimaki et al.), 2005/0031986 (Kakino et al.), 2006/0068328 (Aimura et al), and 2006/0199097 (Oda et al.).

“Violet”-sensitive imageable elements having developability in lower pH developers are described in U.S. Patent Application Publication 2007/020563 (Inno). UV and visible-sensitive imageable elements are also described in WO 2004/074930 (Baumann et al.) and WO 2007/090550 (Strehmel et al.).

Development using gums is described for example, in EP Publications 1,751,625 (Van Damme et al. published as WO 2005/111727) 1,788,429 (Loccufier et al. et al.), 1,788,430 (Williamson et al.), 1,788,431 (Van Damme et al.), 1,788,434 (Van Damme et al.), 1,788,441 (Van Damme), 1,788,442 (Van Damme), 1,788,443 (Van Damme), 1,788,444 (Van Damme), and 1,788,450 (Van Damme), and WO 2007/057442 (Gries et al.).

Copending and commonly assigned U.S. Ser. No. 11/872,772, that was filed Oct. 16, 2007 by K. Ray, Ting, Miller, Clark, and Roth, describe negative-working imageable elements that are sensitive to infrared radiation. Such elements, when imaged, can be processed using gum solutions.

### PROBLEM TO BE SOLVED

The various negative-working compositions and elements described in the art can be readily used to prepare negative-working imageable elements. However, most of these elements are generally developed using alkaline developers, some of which contain organic solvents. There is a desire in the lithographic art, however, to process imaged negative-working imageable elements in a manner that is more environmentally friendly using solutions that are less toxic and corrosive.

### SUMMARY OF THE INVENTION

The present invention provides a method of providing an image comprising:

A) using a laser providing violet radiation, imagewise exposing a negative-working imageable element comprising a substrate having thereon an outermost negative-working imageable layer to provide exposed and non-exposed regions,
the outermost negative-working imageable layer comprising:
a free radically polymerizable component,
an initiator composition capable of generating free radicals sufficient to initiate polymerization of free radically polymerizable groups upon exposure to imaging violet radiation,
a sensitizer for violet irradiation,
a primary polymeric binder that is represented by the following Structure (I):

-(A)_{w}-(A′)_{w′}- (I)

wherein A represents recurring units comprising a pendant reactive vinyl group, A′ represents recurring units other than those represented by A, w is from about 1 to about 70 mol %, and w′ is from about 30 to about 99 mol %, and
an additive that is represented by the following Structure (II):

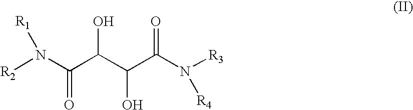

wherein R₁, R₂, R₃, and R₄ are independently hydrogen or alkyl, alkenyl, cycloalkyl, or aryl groups,

B) with or without a post-exposure baking step, contacting the imagewise exposed element with a gum to remove predominantly only the non-exposed regions to provide an image in the developed element.

In some embodiments, the method of this invention includes imagewise exposure that is carried out using imaging violet radiation having a λₘₐₓ of from about 390 to about 430 nm,

the free radically polymerizable component is an ethylenically unsaturated free-radical polymerizable monomer, oligomer, or crosslinkable polymer.

the initiator composition comprises a 2,4,5-triarylimidazolyl dimer and a thiol,

the violet sensitizer is a 2,4,5-triaryloxazole derivative,

the polymeric binder is represented by the following Structure (IA):

-(A)_{w}-(B)ₓ—(C)_{y}-(D)_{z}- (IA)

wherein said A recurring units are derived from at least an allyl (meth)acrylate or styryl (meth)acrylate, said B recurring units are derived from one or more of (meth)acrylonitrile, said C recurring units are derived from one or more of (meth)acrylic acid, 4-carboxyphenyl (meth)acrylate, and 4-carboxystyrene, said D recurring units are derived from one or more of vinyl carbazole, methyl (meth)acrylate, poly(ethylene glycol) methyl ether (meth)acrylate, and a styrene monomer, w is from about 5 to about 50 mol %, x is from about 30 to about 70 mol %, y is from about 5 to about 20 mol %, and z is from 10 to about 40 mol %, and

the additive is N,N′-diallyltartardiamide, N,N′-dibenzyltartardiamide, or N,N,N′,N′-tetramethyltartardiamide, or a combination thereof, and is present in an amount of from about 2 to about 10 weight %,

the gum is a pre-bake gum having a pH of from about 6.5 to about 10, and comprises an alkyldiphenyloxide disulfonate in an amount of from about 2 to about 30 weight %, and

the imaged and developed element is a lithographic printing plate having an aluminum-containing hydrophilic substrate.

With the present invention, imaged negative-working imageable elements can be processed without the use of high pH, toxic, and corrosive developers. Instead, processing can be carried out using certain gums. The processed elements are also advantageous in that they do not require an oxygen barrier overcoat layer over the imageable layer. Rather, the imageable layer is the outermost layer of the element. Thus, the imageable elements used in this invention are simpler in construction without loss in imaging and developing properties.

### DETAILED DESCRIPTION OF THE INVENTION

### Definitions

Unless the context indicates otherwise, when used herein, the terms “imageable element”, “lithographic printing plate precursor”, and “printing plate precursor” are meant to be references to embodiments useful in the present invention.

In addition, unless the context indicates otherwise, the various components described herein such as “primary polymeric binder”, “initiator”, “co-initiator”, “free radically polymerizable component”, “sensitizer”, “secondary polymeric binder”, and similar terms also refer to mixtures of such components. Thus, the use of the articles “a”, “an”, and “the” is not necessarily meant to refer to only a single component.

Moreover, unless otherwise indicated, percentages refer to percents by dry weight, for example, weight % based on either total solids of a coating formulation or total dry layer coverage. Unless otherwise indicated, it is to be understood that any weight percentages described herein are to be interpreted equally for the radiation-sensitive composition or formulation or the dry coated layer.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

“Graft” polymer or copolymer refers to a polymer having a side chain that has a molecular weight of at least 200.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Radiation-Sensitive Compositions

The imageable elements include an ultraviolet (UV) or “violet” radiation-sensitive (imaging) composition disposed on a suitable substrate to form an imageable layer. The imageable elements may have any utility wherever there is a need for an applied coating that is polymerizable using suitable UV radiation, and particularly where it is desired to remove non-exposed regions of the coating instead of exposed regions. The radiation-sensitive compositions can be used to prepare an imageable layer in imageable elements such as printed circuit boards for integrated circuits, microoptical devices, color filters, photomasks, and printed forms such as lithographic printing plate precursors that are defined in more detail below.

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used.

Suitable ethylenically unsaturated components that can be polymerized or crosslinked include ethylenically unsaturated polymerizable monomers that have one or more of the polymerizable groups, including unsaturated esters of alcohols, such as acrylate and methacrylate esters of polyols. Oligomers and/or prepolymers, such as urethane acrylates and methacrylates, epoxide acrylates and methacrylates, polyester acrylates and methacrylates, polyether acrylates and methacrylates, hyperbranched polyester acrylates, dendritic polyester acrylates, and unsaturated polyester resins can also be used. In some embodiments, the free radically polymerizable component comprises carboxy groups.

Useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers. Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), Sartomer 415 [ethoxylated (20)trimethylolpropane triacrylate], and Sartomer CN2302 (hyperbranched polyester acrylate oligomer) that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, N.Y., 1992, pp. 399-440, and in “Polymer Imaging” by A. B. Cohen and P. Walker, in Imaging Processes and Material, J. M. Sturge et al. (Eds.), Van Nostrand Reinhold, N.Y., 1989, pp. 226-262. For example, useful free radically polymerizable components are also described in EP 1,182,033A1 (Fujimaki et al.), beginning with paragraph [0170], and in U.S. Pat. Nos. 6,309,792 (Hauck et al.), 6,569,603 (Furukawa), and 6,893,797 (Munnelly et al.). The free radically polymerizable component can also include carboxy groups as described for example in U.S. Pat. No. 7,153,632 (Saraiya et al.).

Also useful as free radically polymerizable components are the non-polymeric polymerizable compounds having 1H-tetrazole groups that are described in copending and commonly assigned U.S. Ser. No. 11/______ that was filed on ______, 2007 by Baumann, Dwars, Strehmel, Simpson, Savariar-Hauck, and Hauck, and is entitled IMAGEABLE ELEMENTS WITH COMPONENTS HAVING 1H-TETRAZOLE GROUPS (Attorney Docket 94384/JLT), and which is incorporated herein by reference with respect to those polymerizable compounds.

The one or more free radically polymerizable components (monomeric, oligomeric, or polymeric) can be present in the radiation-sensitive composition in an amount of at least 10 weight % and up to 70 weight %, and typically from about 20 to about 50 weight %. The weight ratio of the free radically polymerizable component to the total polymeric binders (described below) is generally from about 5:95 to about 95:5, and typically from about 10:90 to about 90:10, or even from about 30:70 to about 70:30.

The radiation-sensitive composition also includes an initiator composition that is capable of generating free radicals sufficient to initiate polymerization of all the various free radically polymerizable components upon exposure of the composition to imaging radiation. The initiator composition is generally responsive to UV (or violet) imaging radiation corresponding to the spectral range of at least 300 nm and up to and including 500 nm (typically from about 350 to about 475 nm). Initiator compositions are used that are appropriate for the desired imaging wavelength(s).

Useful initiators compositions include but are not limited to, one or more compounds chosen from any of the following classes of compounds (A) through (H) described below, or one or more compounds from multiple classes of compounds:

(A) Metallocenes are organometallic compounds having one or more cyclopentadienyl ligands that are optionally substituted at one or all of the ring carbons. Each carbon in the five-member ligand ring is coordinated to the transition metal center. Metallocenes are known for having a wide variety of transition metals including iron, titanium, tungsten, molybdenum, nickel, cobalt, chromium, zirconium, and manganese.

For example, ferrocenes have an iron center coordinated by at least one cyclopentadienyl ligand, but ferrocenes also include bicyclopentadienyl “sandwich” compounds. Suitable ferrocene compounds include those that have a hexhapto benzene ligand coordinated to the iron center. Examples of such compounds are described in Col. 7 of U.S. Pat. No. 6,936,384 (Munnelly et al.). Other suitable ferrocenes include compounds having halogenated, aryl-substituted, or haloaryl-substituted cyclopentadienyl ligands.

Titanocenes are also useful. Such compounds have a titanium center coordinated by at least one pentahapto cyclopentadienyl ligand and generally include additional ligands that may be known for organometallic complexes. Some suitable titanocene compounds include in their structures aryl ligands, haloaryl ligands, or pyrrole-substituted aryl ligands. Examples of useful titanocenes include those described in Col. 8 of U.S. Pat. No. 6,936,384 (noted above). One commercially available titanocene is (bis)cyclopentadienyl-(bis)2,6-difluoro-3-(pyrr-1-yl)phen-1-yl titanium sold by Ciba Specialty Chemicals as Irgacure® 784, as noted below with the Examples. Other suitable titanocenes are described in U.S. Pat. Nos. 4,548,891 (Riediker et al.), 4,590,287 (Riediker et al.), 5,008,302 (Husler et al.), 5,106,722 (Husler et al.), 6,010,824 (Komano et al.), and 6,153,660 (Fujimaki et al.).

(B) Azines, for example, as described for example in U.S. Pat. No. 6,936,384 (Munnelly et al.). These compounds are organic heterocyclic compounds containing a 6-membered ring formed from carbon and nitrogen atoms. Azine compounds include heterocyclic groups such as pyridine, diazine, and triazine groups, as well as polycyclic compounds having a pyridine, diazine, or triazine substituent fused to one or more aromatic rings such as carbocyclic aromatic rings. Thus, the azine compounds include, for example, compounds having a quinoline, isoquinoline, benzodiazine, or naphthodiazine substituent. Both monocyclic and polycyclic azine compounds are useful.

Useful azine compounds are triazine compounds that include a 6-membered ring containing 3 carbon atoms and 3 nitrogen atoms such as those described in U.S. Pat. Nos. 6,309,792 (Hauck et al.), 6,010,824 (Komano et al.), 5,885,746 (Iwai et al), 5,496,903 (Watanabe et al.), and 5,219,709 (Nagasaka et al.).

The azinium form of azine compounds can also be used if desired. In azinium compounds, a quaternizing substituent of a nitrogen atom in the azine ring is capable of being released as a free radical. The alkoxy substituent that quaternizes a ring nitrogen atom of the azinium nucleus can be selected from among a variety of alkoxy substituents.

Halomethyl-substituted triazines, such as trihalomethyl triazines, are useful in the initiator composition. Representative compounds of this type include but are not limited to, 1,3,5-triazine derivatives such as those having 1 to 3-CX₃ groups wherein X independently represent chlorine or bromine atoms, including polyhalomethyl-substituted triazines and other triazines, such as 2,4-trichloromethyl-6-methoxyphenyl triazine, 2-phenyl-4,6-bis(trichloromethyl)-s-triazine, 2,4,6-tris(trichloromethyl)-s-triazine, 2-methyl-4,6-bis(trichloromethyl)-s-triazine, 2-(styryl-4,6-bis(trichloromethyl)-s-triazine, 2-(p-methoxystyryl)-4,6-bis(trichloromethyl)-s-triazine, 2-(4-methoxy-naphtho-1-yl)-4,6-bis(trichloromethyl)-s-triazine, 2-(4-ethoxynaphtho-lyl)-4,6-bis(trichloromethyl)-s-triazine, and 2-(4-(2-ethoxyethyl)-naphtho-1-yl)-4,6-bis(trichloromethyl)-s-triazine], 2-(4-methylthiophenyl)-4,6-bis(trichloromethyl)-2-triazine, 2-(4-chlorophenyl-4,6-bis(trichloromethyl)-2-triazine, 2,4,6-tri(trichloromethyl)-2-triazine, and 2,4,6-tri(tribromomethyl)-2-triazine.

(C) Peroxides such as benzoyl peroxide and hydroperoxides such as cumyl hydroperoxide and other organic peroxides described for example in EP 1,035,435 (Sorori et al.).

(D) 2,4,5-Triarylimidazolyl dimers (also known as hexaarylbiimidazoles, or “HABI's”) as described for example in U.S. Pat. No. 4,565,769 (Dueber et al.). Examples of such compounds include but are not limited to, 2,2′-bis(o-chlorophenyl)-4,4′,5,5′-tetraphenylbiimidazole and 2,2′-bis(o-chlorophenyl)-4,4′5,5′-tetra(m-methoxyphenyl)biimidazole. Other useful “HABI's” are described by formula (V) and the listed examples on pages 25-27 of WO 07/090,550 (Strehmel et al.) that is incorporated herein by reference for the disclosure of these compounds.

(E) Onium salts such as ammonium, iodonium, sulfonium salts, phosphonium, oxylsulfoxonium, oxysulfonium, diazonium, selenonium, arsenonium, and pyridinium salts. Useful iodonium salts are well known in the art and include but not limited to, U.S. Patent Application Publication 2002/0068241 (Oohashi et al.), WO 2004/101280 (Munnelly et al.), and U.S. Pat. Nos. 5,086,086 (Brown-Wensley et al.), 5,965,319 (Kobayashi), and 6,051,366 (Baumann et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N⁺). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art. Halonium salts are useful onium salts. In one embodiment, the onium salt has a positively-charged iodonium, (4-methylphenyl)[4-(2-methylpropyl)phenyl]-moiety and a suitable negatively charged counterion. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

(F) Oxime esters or oxime ethers such as those derived from benzoin.

(G) N-phenyl glycine and derivatives thereof including compounds that have additional carboxy groups and can be considered polycarboxylic acids or anilino diacetic acids. Examples of such compounds include but are not limited to, N-phenylglycine and the glycine derivatives described in [0054] of WO 03/066338 (Timpe et al.).

(H) Thiol compounds such as heterocyclic mercapto compounds including mercaptotriazoles, mercaptobenzimidazoles, mercaptooxadiazoles, methcaptotetrazines, mercaptoimidazoles, mercaptopyridines, mercaptooxazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole. Other useful compounds are described in the paragraph bridging pages 24-25 of WO 07/090,550 (Strehmel et al.) that is incorporated herein for the disclosure of these compounds.

In some embodiments, useful initiator compositions include a combination of a 2,4,5-triarylimidazolyl dimer and a thiol compound, such as either 2,2′-bis(o-chlorophenyl)-4,4′,5,5′-tetraphenylbiimidazole or 2,2′-bis(o-chlorophenyl)-4,4′5,5′-tetra(m-methoxyphenyl)biimidazole in combination with a thiol compound such as a mercaptotriazole.

Other useful initiator compositions can include an onium salt such as an iodonium salt as described above in combination with a metallocene (for example a titanocene or ferrocene) as described for example in U.S. Pat. No. 6,936,384 (noted above).

The free radical generating compounds in the initiator composition are generally present in the radiation-sensitive composition in an amount of at least 0.5% and up to and including 30%, and typically at least 2 and up to and including about 20%. The optimum amount of the various initiator components may differ for various compounds and the sensitivity of the radiation-sensitive composition that is desired and would be readily apparent to one skilled in the art.

The radiation-sensitive composition (and imageable element) generally includes one or more imaging radiation absorbing chromophores, or sensitizers, that spectrally sensitize the composition to a wavelength of from about 300 nm and up to and including 500 nm, typically from about 350 to about 475 nm, and more typically from about 390 to about 430 nm.

Useful sensitizers include but are not limited to, certain pyrilium and thiopyrilium dyes and 3-ketocoumarins. Some other useful sensitizers for such spectral sensitivity are described for example, in 6,908,726 (Korionoff et al.), WO 2004/074929 (Baumann et al.) that describes useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated π-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

Other useful sensitizers are the 2,4,5-triaryloxazole derivatives as described in WO 2004/074930 (Baumann et al.). These compounds can be used alone or with a co-initiator as described above. Useful 2,4,5-triaryloxazole derivatives can be represented by the Structure G-(Ar₁)₃ wherein Ar₁ is the same or different, substituted or unsubstituted carbocyclic aryl group having 6 to 12 carbon atoms in the ring, and G is a furan or oxazole ring, or the Structure G-(Ar₁)₂ wherein G is an oxadiazole ring. The Ar₁ groups can be substituted with one or more halo, substituted or unsubstituted alkyl, substituted or unsubstituted cycloalkyl, substituted or unsubstituted aryl, amino (primary, secondary, or tertiary), or substituted or unsubstituted alkoxy or aryloxy groups. Thus, the aryl groups can be substituted with one or more R′₁ through R′₃ groups, respectively, that are independently hydrogen or a substituted or unsubstituted alkyl group having from 1 to 20 carbon atoms (such as methyl, ethyl, iso-propyl, n-hexyl, benzyl, and methoxymethyl groups) substituted or unsubstituted carbocyclic aryl group having 6 to 10 carbon atoms in the ring (such as phenyl, naphthyl, 4-methoxyphenyl, and 3-methylphenyl groups), substituted or unsubstituted cycloalkyl group having 5 to 10 carbon atoms in the ring, a —N(R′₄)(R′₅) group, or a —OR′₆ group wherein R′₄ through R′₆ independently represent substituted or unsubstituted alkyl or aryl groups as defined above. At least one of R′₁ through R′₃ is an —N(R′₄)(R′₅) group wherein R′₄ and R′₅ are the same or different alkyl groups. Useful substituents for each Ar₁ group include the same or different primary, secondary, and tertiary amines.

Still another class of useful violet/visible radiation sensitizers includes compounds represented by the Structure Ar₁-G-Ar₂ wherein Ar₁ and Ar₂ are the same or different substituted or unsubstituted aryl groups having 6 to 12 carbon atoms in the ring, or Ar₂ can be an arylene-G-Ar₁ or arylene-G-Ar₂ group, and G is a furan, oxazole, or oxadiazole ring. Ar₁ is the same as defined above, and Ar₂ can be the same or different aryl group as Ar₁. “Arylene” can be any of the aryl groups defined for Ar₁ but with a hydrogen atom removed to render them divalent in nature.

For example, useful sensitizers are defined by the following Formula:

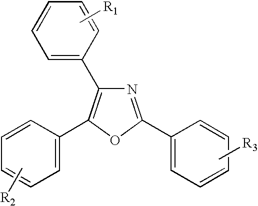

wherein R₁, R₂ and R₃ independently represent a hydrogen atom, alkyl, aryl or aralkyl group that may be substituted, an —NR₄R₅-group (R₄ and R₅ representing an alkyl, aryl or aralkyl group), or —OR₆ group (R₆ representing an alkyl, aryl or aralkyl group). Particularly useful compounds of this Formula contain at least one of substituent R₁, R₂, and R₃ that represents a donor group, such as an amino group (for example, an dialkylamino group). These compounds can be made following the procedure given in DE 1,120,875 (Sues et al.) and EP 129,059 (Hayashida).

EP 684,522 (noted above) describes radiation-sensitive compositions and imageable elements containing one or more dyes that have a spectral absorption in the range of from about 250 nm to about 700 nm.

The sensitizer can be present in the radiation-sensitive composition in an amount generally of at least 1% and up to and including 30% and typically at least 3 and up to and including 20%. The particular amount needed for this purpose would be readily apparent to one skilled in the art, depending upon the specific compound used to provide the desired chromophore.

The radiation-sensitive composition includes one or more primary polymeric binders that have one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups may be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.). Other useful polymeric binders have vinyl groups in pendant groups that are described, for example in EP 1,182,033A1 (Fujimaki et al.) and U.S. Pat. Nos. 4,874,686 (Urabe et al.) and 7,041,416 (Wakata et al.) that are incorporated by reference, especially with respect to the general formulae (I) through (3) noted in EP 1,182,033A1.

For example, the reactive vinyl group can be represented by the structure: —X—CR¹═C(R²)R³ wherein X, R¹, R², and R³ are defined below.

Useful primary polymeric binders can be represented by the following Structure (I):

-(A)_{w}-(A′)_{w′} (I)

wherein A represents recurring units comprising one or more pendant reactive vinyl groups that are directly or indirectly attached to the hydrophobic polymeric backbone, A′ represents recurring units other than those represented by A, w is from about 1 to about 70 mol %, and w′ is from about 30 to about 99 mol %. Thus, the A′ recurring units contain no pendant reactive vinyl groups.

For example, the reactive vinyl groups can be connected to the polymer backbone with a carbon-carbon direct bond or a linking group. For example, useful reactive vinyl groups are shown in Structure IIa and IIb below as Z′ groups. The X linking groups may be an oxy (—O—), thio (—S—), carbonyloxy [—C(O)O—], carbonamido [—C(O)NR′—], carbonyl [—C(O)—], amido (—NR′—), sulfonyl [—S(═O)₂O—], substituted or unsubstituted arylene group (such as a substituted or unsubstituted phenylene group), or a substituted or unsubstituted alkylene group (having 1 to 10 carbon atoms, such as a methylene group), or combinations of two or more of these groups. In particular, X may be an oxy, thio, —NR′—, or substituted or unsubstituted arylene group having 6 to 10 carbon atoms in the ring (such as substituted or unsubstituted phenylene). R′ can be hydrogen, a substituted or unsubstituted alkyl group having 1 to 6 carbon atoms, or a substituted or unsubstituted aryl group having 6 or 10 carbon atoms in the ring. In many embodiments, X is a direct bond or a carbonyloxymethylene or a methyleneoxyphenylene group.

Z′ is represented by the following Structure (IIa) or (IIb):

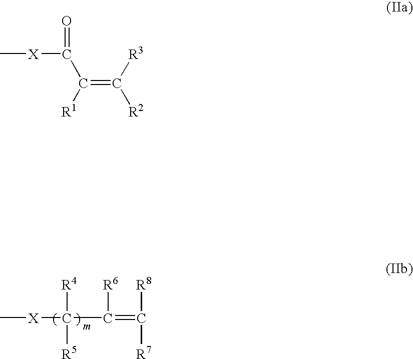

wherein X is defined as above.

R¹ to R⁸ independently represent monovalent organic groups of which there are hundreds of possibilities including but not limited to, hydrogen, substituted or unsubstituted alkyl groups having 1 to 10 carbon atoms, substituted or unsubstituted cycloalkyl groups having 5 to 10 carbon atoms in the unsaturated ring, substituted or unsubstituted aryl groups having 6 to 10 carbon atoms in the aromatic ring, substituted or unsubstituted heterocyclyl groups having 5 to 10 carbon, nitrogen, sulfur, or oxygen atoms in the aromatic or non-aromatic rings, cyano, halo, and vinyl groups.

When the pendant groups comprise the moiety represented by Structure IIb, R⁴ and R⁵ can be independently hydrogen or a substituted or unsubstituted alkyl group having 1 to 3 carbon atoms, and R⁶ to R⁸ can be independently hydrogen, or a halo group, substituted or unsubstituted alkyl group having 1 to 6 carbon atoms, or a substituted or unsubstituted phenyl group. For example, R⁶ to R⁸ can be independently hydrogen or a chloro, methyl, ethyl, or phenyl groups.

In Structure IIb, m is 0 or 1, and preferably it is 1.

For example, Z′ can be represented by the following Structure IIc:

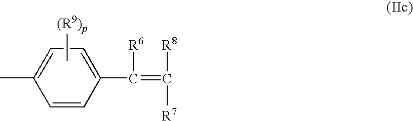

wherein R⁶ through R⁸ are as defined above, R⁹ is a substitutable group or atom that would be readily apparent to one skilled in the art, and p is an integer of 0 to 4. Most preferably, p is 0, and R⁶ through R⁸ are all hydrogens.

Some useful pendant reactive vinyl groups are alkenyl groups including but not limited to allyl esters, styryl, and (meth)acryloyl groups. For example, such groups can be provided by allyl (meth)acrylates, or by reacting a polymer precursor with an allyl halide, 4-vinylbenzyl chloride, or (meth)acryloyl chloride using conditions that would be apparent to a skilled worker in the art.

The A′ recurring units can be derived from one or more of the polymerizable ethylenically unsaturated monomers that are described below for the B, C, and D recurring units. Generally, recurring units from at least one monomer from each of the B, C, and D groups are present in the desired molar amounts described below.

In some embodiments, the primary polymeric binder can be represented by the following Structure (IA):

-(A)_{w}-(B)ₓ—(C)_{y}-(D)_{z}- (IA)

wherein A represents recurring units comprising a pendant allyl (meth)acrylate group that is directly or indirectly attached to the hydrophobic polymer backbone, B represents recurring units comprising pendant cyano groups, C represents recurring units comprising pendant acidic groups, D represents recurring units other than those represented by A, B, and C, w is from about 1 to about 70 mol %, x is from about 10 to about 80 mol %, y is from about 1 to about 30 mol %, and z is from 0 to about 90 mol %,

In other embodiments, w is from about 5 to about 50 mol %, x is from about 30 to about 70 mol %, y is from about 5 to about 20 mol %, and z is from 0 to about 60 mol % (or z can be from about 10 to about 40 mol %).

The B recurring units are generally derived from one or more of (meth)acrylonitrile, cyanostyrenes, or cyano(meth)acrylates. The (meth)acrylonitriles are particularly useful.

The C recurring units comprise one or more acidic groups such as carboxy, phosphoric acid, and sulfonic acid, as well as salts thereof (carboxylates, sulfonates, etc.). Monomers from such recurring units can be derived include but are not limited to, carboxy-containing vinyl monomers, carboxylated styrenes, and sulfated styrenes. Ethylenically unsaturated polymerizable monomers that have carboxy groups, or that have reactive groups that can be converted to carboxy groups, or to which carboxy groups can be attached after polymerization, are particularly useful. Thus, the carboxy groups can be obtained from a number of synthetic methods. Useful monomers having pendant carboxylic acid groups include but are not limited to, (meth)acrylic acid, 4-carboxyphenyl (meth)acrylate, and 4-carboxystyrene.

The D recurring units are derived from one or more of vinyl carbazole or vinyl carbazole derivatives as described in U.S. Pat. No. 7,175,949 (Tao et al.), alkyl (meth)acrylates [such as methyl (meth)acrylates], (meth)acrylamides, N-phenyl maleimides, poly(alkylene glycol) methyl ether (meth)acrylates [such as poly(ethylene glycol) methyl ether (meth)acrylates], and styrene monomers such as substituted and unsubstituted styrene. Useful combinations of D recurring units include a combination of recurring units derived from two or more of a methyl (meth)acrylate, an N-vinyl carbazole, and a polyethylene glycol methyl ether (meth)acrylate. These are merely provided as examples and not intended to be limiting since a skilled artisan could use many other ethylenically unsaturated polymerizable monomers.

In some embodiments, the A recurring units are derived from at least an allyl(meth)acrylate, the B recurring units are derived from one or more of (meth)acrylonitrile, the C recurring units are derived from one or more of (meth)acrylic acid, 4-carboxyphenyl (meth)acrylate, and 4-carboxystyrene, the D recurring units are derived from one or more of vinyl carbazole, methyl (meth)acrylate, poly(ethylene glycol) methyl ether (meth)acrylate, and a styrene monomer.

The primary polymeric binder is generally present in the radiation-sensitive composition in an amount of from about 10 to about 70%, based on the total imageable layer dry weight. These binders may comprise up to 100% of the dry weight of all polymeric binders (primary polymeric binders plus any secondary polymeric binders).

The radiation-sensitive composition further includes one or more “additives” that are represented by the following Structure (II):

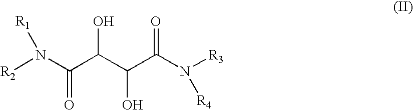

wherein R₁, R₂, R₃, and R₄ are independently hydrogen or alkyl, alkenyl, cycloalkyl, or aryl groups.

The alkyl groups can be substituted or unsubstituted, linear or branched and have 1 to 15 carbon atoms (such as methyl, ethyl, isopropyl, t-butyl, n-hexyl, benzyl, decyl, dodecyl, and others readily apparent to a skilled artisan). Possible substituents include but are not limited to, aryl (such as phenyl), alkyl (such as methyl or ethyl), and halo (such as chloro or bromo). The alkenyl groups can also be substituted or unsubstituted, linear or branched, and have 2 to 10 carbon atoms (such as ethenyl, allyl, butenyl isomers, pentenyl isomers, hexenyl isomers, and octenyl isomers). Possible substituents are the same as for the alkyl groups. The cycloalkyl groups can be substituted or unsubstituted and have 5 to 10 carbon atoms in the carbocyclic ring (such as cyclopentyl, cyclohexyl, 4-methylcyclohexyl, and 4-bromocyclopentyl). Possible substituents are the same as for the alkyl groups. The aryl groups can be substituted or unsubstituted and have 6 or 10 carbon atoms in the aromatic ring (such as phenyl, 4-methylphenyl, and naphthyl). Possible substituents are the same as for the alkyl groups.

For example, R₁, R₂, R₃, and R₄ are independently substituted or unsubstituted alkyl groups having 1 to 10 carbon atoms (as defined above), substituted or unsubstituted alkenyl groups having 2 to 8 carbon atoms (as defined above), or substituted or unsubstituted phenyl or naphthyl groups.

Examples of useful additives are N,N′-diallyltartardiamide, N,N′-dibenzyltartardiamide, N1-decyl-N4-dodecyl-2,3-dihydroxybutanediamide, N1,N4-di-2-butene-1-yl-2,3-dihydroxybutanediamide, 2,3-dihydroxy-N1,N4-di-2-pentene-1-yl-butanediamide, and N,N,N′,N′-tetramethyltartardiamide. Combinations of two or more of these compounds can also be used. Such compounds are readily available from a number of commercial sources including Aldrich Chemical Company (Milwaukee, Wis.).

Such additives are generally present in the radiation-sensitive composition in an amount of at least 2 and up to 10 weight %, and typically from about 4 to about 8 weight %.

Additional polymeric binders (“secondary” polymeric binders) may also be used in the radiation-sensitive composition in addition to the primary polymeric binders. Such polymeric binders can be any of those known in the art for use in negative-working radiation-sensitive compositions other than those mentioned above. The secondary polymeric binder(s) may be present in an amount of from about 1.5 to about 70 weight % and typically from about 1.5 to about 40%, based on the dry coated weight of the radiation-sensitive composition, and it may comprise from about 30 to about 60 weight % of the dry weight of all polymeric binders.

The secondary polymeric binders may be homogenous, that is, dissolved in the coating solvent, or may exist as discrete particles. Such secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (Fujimaki et al.) and U.S. Pat. Nos. 6,309,792 (Hauck et al.), 6,352,812 (Shimazu et al.), 6,569,603 (Furukawa et al.), and 6,893,797 (Munnelly et al.). Also useful are the vinyl carbazole polymers described in copending and commonly assigned U.S. Pat. No. 7,175,949 (Tao et al.). Copolymers of polyethylene glycol methacrylate/acrylonitrile/styrene in particulate form, dissolved copolymers derived from carboxyphenyl methacrylamide/acrylonitrile/methacrylamide/N-phenyl maleimide, copolymers derived from polyethylene glycol methacrylate/acrylonitrile/vinylcarbazole/-styrene/methylacrylic acid, copolymers derived from N-phenyl maleimide/methacrylamide/methacrylic acid, copolymers derived from urethane-acrylic intermediate A (the reaction product of p-toluene sulfonyl isocyanate and hydroxylethyl methacrylate)/acrylonitrile/N-phenyl maleimide, and copolymers derived from N-methoxymethyl methacrylamide/methacrylic acid/acrylonitrile/n-phenylmaleimide are useful.

Other useful secondary polymeric binders are particulate poly(urethane-acrylic) hybrids that are distributed (usually uniformly) throughout the imageable layer. Each of these hybrids has a molecular weight of from about 50,000 to about 500,000 and the particles have an average particle size of from about 10 to about 10,000 nm (typically from about 30 to about 500 nm and or from about 30 to about 150 nm). These hybrids can be either “aromatic” or “aliphatic” in nature depending upon the specific reactants used in their manufacture. Blends of particles of two or more poly(urethane-acrylic) hybrids can also be used. For example, a blend of Hybridur® 570 polymer dispersion with Hybridur® 870 polymer dispersion could be used.

Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that may also include commercial surfactants, anti-foaming agents, dispersing agents, anti-corrosive agents, and optionally pigments and water-miscible organic solvents. Further details about each commercial Hybridur® polymer dispersion can be obtained by visiting the Air Products and Chemicals, Inc. website.

The radiation-sensitive composition can further comprise one or more phosphate (meth)acrylates, each of which has a molecular weight generally greater than 200 and typically at least 300 and up to and including 1000. By “phosphate (meth)acrylate” we also mean to include “phosphate methacrylates” and other derivatives having substituents on the vinyl group in the acrylate moiety.

Each phosphate moiety is typically connected to an acrylate moiety by an aliphatic chain [that is, an -(aliphatic-O)— chain] such as an alkyleneoxy chain [that is an -(alkylene-O)ₘ— chain] composed of at least one alkyleneoxy unit, in which the alkylene moiety has 2 to 6 carbon atoms and can be either linear or branched and m is 1 to 10. For example, the alkyleneoxy chain can comprise ethyleneoxy units, and m is from 2 to 8 or m is from 3 to 6. The alkyleneoxy chains in a specific compound can be the same or different in length and have the same or different alkylene group.

Useful phosphate (meth)acrylates can be represented by the following Structure (III):

P(═O)(OM)ₙ(OR)₃₋ₙ (III)

wherein n is 1 or 2, M is hydrogen or a monovalent cation (such as an alkali metal ion, ammonium cations including cations that include one to four hydrogen atoms). For example, useful M cations include but are not limited to sodium, potassium, —NH₄, —NH(CH₂CH₂OH)₃, and —NH₃(CH₂CH₂OH). When n is 2, the M groups are the same or different. The compounds wherein M is hydrogen are particularly useful.

The R groups are independently the same or different groups represented by the following Structure (IV):

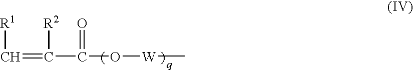

wherein R¹ and R² are independently hydrogen, or a halo (such as chloro or bromo) or substituted or unsubstituted alkyl group having 1 to 6 carbon atoms (such as methyl, chloromethyl, methoxymethyl, ethyl, isopropyl, and t-butyl groups). In many embodiments, one or both of R¹ and R² are hydrogen or methyl, and in some embodiments, R¹ is hydrogen and R² is methyl).

W is an aliphatic group having at least 2 carbon or oxygen atoms, or combination of carbon and oxygen atoms, in the chain, and q is 1 to 10. Thus, W can include one or more alkylene groups having 1 to 8 carbon atoms that are interrupted with one or more oxygen atoms (oxy groups), carbonyl, oxycarbonyl, or carbonyl oxy groups. For example, one such aliphatic group is an alkylenecarbonyloxyalkylene group. Useful alkylene groups included in the aliphatic groups have 2 to 5 carbon atoms and can be branched or linear in form.

The R groups can also independently be the same or different groups represented by the following Structure (V):

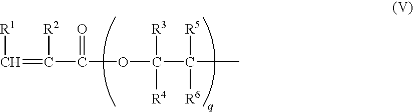

wherein R¹, R², and q are as defined above and R³ through R⁶ are independently hydrogen or a substituted or unsubstituted alkyl group having 1 to 6 carbon atoms (such as methyl, methoxymethyl), ethyl, chloromethyl, hydroxymethyl, ethyl, iso-propyl, n-butyl, t-butyl, and n-pentyl groups). Typically, R³ through R⁶ are independently hydrogen or methyl, and in most embodiments, all are hydrogen.

In Structures IV and V, q is 1 to 10, or from 2 to 8, for example from 3 to 6.

Representative phosphate (meth)acrylates useful in this invention include but are not limited to, ethylene glycol methacrylate phosphate (available from Aldrich Chemical Co.), a phosphate of 2-hydroxyethyl methacrylate that is available as Kayamer PM-2 from Nippon Kayaku (Japan) that is shown below, a phosphate of a di(caprolactone modified 2-hydroxyethyl methacrylate) that is available as Kayamer PM-21 (Nippon Kayaku, Japan) that is also shown below, and a polyethylene glycol methacrylate phosphate with 4-5 ethoxy groups that is available as Phosmer PE from Uni-Chemical Co., Ltd. (Japan) that is also shown below, or as Sipomer PAM 100 that is available from Rhodia Inc, (Cranbury, N.J.). Still other useful compounds of this type are commercially available from Sartomer Company, Inc. (Exton, Pa.) as Sartomer SR 705, SR 9011, SR 9012, CD 9050, CD 9051, and CD 9053. Other representative phosphate (meth)acrylates useful in this invention are described for example, in U.S. Pat. No. 7,175,969 (Ray et al.).

The phosphate acrylate can be present in an amount of at least 0.5 and up to and including 20 weight % and typically at least 0.9 and up to and including 10 weight %.

The radiation-sensitive composition can further comprise one or more trialkoxysilylalkyl (meth)acrylates or vinyl trialkoxysilanes, each of which has a molecular weight generally greater than 120 and typically at least 145 and up to and including 1,000. Representative examples of such compounds are the following compounds:

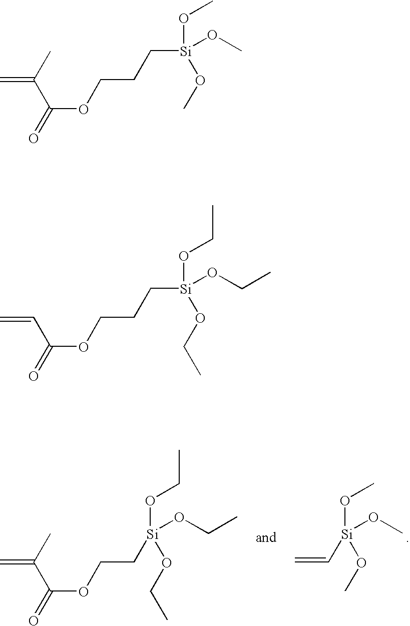

The radiation-sensitive composition can also include a “primary additive” that is a poly(alkylene glycol) or an ether or ester thereof that has a molecular weight of at least 200 and up to and including 4000. This primary additive is present in an amount of at least 2 and up to and including 50 weight %, based on the total dry weight of the imageable layer. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate. Also useful are SR9036 (ethoxylated (30) bisphenol A dimethacrylate), CD9038 (ethoxylated (30) bisphenol A diacrylate), and SR494 (ethoxylated (5) pentaerythritol tetraacrylate), and similar compounds all of which that can be obtained from Sartomer Company, Inc. In some embodiments, the primary additive may be “non-reactive” meaning that it does not contain polymerizable vinyl groups.

The radiation-sensitive composition can also include a “secondary additive” that is a poly(vinyl alcohol), a poly(vinyl pyrrolidone), poly(vinyl imidazole), or polyester in an amount of up to and including 20 weight %.

The radiation-sensitive composition can also include a variety of other optional compounds including but not limited to, dispersing agents, humectants, biocides, plasticizers, surfactants for coatability or other properties, viscosity builders, dyes or colorants to allow visualization of the written image (such as crystal violet, methyl violet, ethyl violet, Victoria blue, malachite green, and brilliant green, and phthalocyanine pigments such as copper phthalocyanine and metal-free phthalocyanine), pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

### Imageable Elements

The imageable elements can be formed by suitable application of a radiation-sensitive composition as described above to a suitable substrate to form an imageable layer. This substrate can be treated or coated in various ways as described below prior to application of the radiation-sensitive composition to improve hydrophilicity. Typically, there is only a single imageable layer comprising the radiation-sensitive composition that is directly applied to the substrate without any intermediate layer. If the substrate has been treated to provide improved adhesion or hydrophilicity, the applied imageable layer is disposed thereon but these treatments are not considered “intermediate layers” for the purpose of this invention.

The imageable element does not include what is conventionally known as an overcoat (also known as an “oxygen impermeable topcoat” or “oxygen barrier layer”) disposed over the imageable layer, for example, as described in EP Patent Publications 1,788,429, 1,788,431 and 1,788,434 (all noted above) and US Patent Application Publication 2005/0266349 (noted above). Such overcoat layers comprise one or more poly(vinyl alcohol)s as the predominant polymeric binders. Thus, the imageable layer is the outermost layer of the imageable element in this invention.

The substrate generally has a hydrophilic surface, or at least a surface that is more hydrophilic than the applied imageable layer on the imaging side. The substrate comprises a support that can be composed of any material that is conventionally used to prepare imageable elements such as lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

One useful substrate is composed of an aluminum support that may be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid or phosphoric acid anodized aluminum support that provides a hydrophilic surface for lithographic printing.

The aluminum support may also be treated with, for example, a silicate, dextrine, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support may be treated with a phosphate solution that may further contain an inorganic fluoride (PF). The aluminum support can be electrochemically-grained, sulfuric acid-anodized, and treated with PVPA or PF using known procedures to improve surface hydrophilicity.

The thickness of the substrate can be varied but should be sufficient to sustain the wear from printing and thin enough to wrap around a printing form. Useful embodiments include a treated aluminum foil having a thickness of at least 100 μm and up to and including 700 μm.

The backside (non-imaging side) of the substrate may be coated with antistatic agents and/or slipping layers or a matte layer to improve handling and “feel” of the imageable element.

The substrate can also be a cylindrical surface having the imageable layer thereon, and thus be an integral part of the printing press. The use of such imaging cylinders is described for example in U.S. Pat. No. 5,713,287 (Gelbart).

A radiation-sensitive composition containing the components described above can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder).

Illustrative of such manufacturing methods is mixing the free radically polymerizable component, primary polymeric binder, initiator composition, sensitizer, additive, and any other components described above in a suitable coating solvent including water, organic solvents [such as glycol ethers including 1-methoxypropan-2-ol, methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], or mixtures thereof, applying the resulting solution to a substrate, and removing the solvent(s) by evaporation under suitable drying conditions. Some representative coating solvents and imageable layer formulations are described in the Examples below. After proper drying, the coating weight of the imageable layer is generally at least 0.1 and up to and including 5 g/m² or at least 0.5 and up to and including 3.5 g/m². Any particulate primary polymeric binders present in the imageable layer may partially coalesce or be deformed during the drying operation.

Once the imageable layer has been applied and dried on the substrate, the imageable element can be enclosed in water-impermeable material that substantially inhibits the transfer of moisture to and from the imageable element. Details of this process are provided in U.S. Pat. No. 7,175,969 (noted above).

### Imaging Conditions

During use, the imageable element is exposed to a suitable source of imaging or exposing radiation such as UV or “violet” radiation, depending upon the sensitizer present in the radiation-sensitive composition, at a wavelength of from about 300 to about 500 nm. For example, imaging can be carried out using imaging or exposing radiation, such as at a wavelength of at least 350 nm and up to and including about 500 nm and typically at least 350 nm and up to and including 475 nm, or from about 390 to about 430 nm. Imaging can be carried out using imaging radiation at multiple wavelengths at the same time if desired.

The laser used to expose the imageable element is usually a diode laser, because of the reliability and low maintenance of diode laser systems, but other lasers such as gas or solid-state lasers may also be used. The combination of power, intensity and exposure time for laser imaging would be readily apparent to one skilled in the art.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum.

Useful UV and “violet” imaging apparatus include Prosetter (from Heidelberger Druckmaschinen, Germany), Luxel Vx-9600 CTP and Luxel V-8 CTP platesetters (from FUJI, Japan), Python (Highwater, UK), MakoNews, Mako 2, Mako 4 or Mako 8 (from ECRM, US), Micra (from Screen, Japan), Polaris and Advantage (from AGFA, Belgium), LaserJet (from Krause, Germany), and Andromeda® A750M (from Lithotech, Germany), imagesetters.

Imaging radiation in the UV or “violet” region of the spectrum can be carried out generally using energies of at least 0.01 mJ/cm² and up to and including 0.5 mJ/cm², and typically at least 0.02 and up to and including about 0.1 mJ/cm². It would be desirable, for example, to image the imageable elements at a power density in the range of at least 0.5 and up to and including 50 kW/cm² and typically of at least 5 and up to and including 30 kW/cm².

### Development and Printing

With or without a post-exposure baking (or pre-heat) step after imaging and before development, the imaged elements can be developed “off-press” using a gum (or gum solution) as described herein. A gum solution is typically an aqueous liquid that comprises one or more surface protective compounds capable of protecting the lithographic image of the printing plate against contamination (for example, oxidation, fingerprints, dust or scratches). There are generally two types of “gum” solutions known in the art: (1) a “bake”, “baking”, or “pre-bake” gum usually contains one or more compounds that do not evaporate at the usual pre-bake temperatures used for making lithographic printing plates, typically an anionic or nonionic surfactant, and (2) a “finisher” gum that usually contains one or more hydrophilic polymers (both synthetic and naturally-occurring, such as gum Arabic cellulosic compounds, (meth)acrylic acid polymers, and polysaccharides) that are useful for providing a protective overcoat on a printing plate. The gums used in the practice of this invention would be generally considered “pre-bake” gums, and thus, usually lack the hydrophilic polymers.

By using this gum for development, the conventional aqueous alkaline developer compositions containing silicates or metasilicates are avoided.

The gum may be provided in diluted or concentrated form. The amounts of components described below refer to amount in the diluted gum that is likely its form for use in the practice of the invention. However, it is to be understood that the present invention includes the use of concentrated gums and the amounts of various components (such as the anionic surfactants) would be correspondingly increased.

The gum used in this invention is an aqueous solution that generally has a pH greater than 6 and up to about 11, and typically from about 6.5 to about 11, or from about 6.5 to about 10, as adjusted using a suitable amount of a base. The viscosity of the gum can be adjusted to a value of from about 1.7 to about 5 cP by adding a suitable amount of a viscosity-increasing compound such as a poly(vinyl alcohol) or poly(ethylene oxide).

In addition, these gums have one or more anionic surfactants as the only essential component, even though optional components (described below) can be present if desired.

Useful anionic surfactants include those with carboxylic acid, sulfonic acid, or phosphonic acid groups (or salts thereof). Anionic surfactants having sulfonic acid (or salts thereof) groups are particularly useful. For example, anionic surfactants can include aliphates, abietates, hydroxyalkanesulfonates, alkanesulfonates, dialkylsulfosuccinates, alkyldiphenyloxide disulfonates, straight-chain alkylbenzenesulfonates, branched alkylbenzenesulfonates, alkylnaphthalenesulfonates, alkylphenoxypolyoxyethylenepropylsulfonates, salts of polyoxyethylene alkylsulfonophenyl ethers, sodium N-methyl-N-oleyltaurates, monoamide disodium N-alkylsulfosuccinates, petroleum sulfonates, sulfated castor oil, sulfated tallow oil, salts of sulfuric esters of aliphate alkylester, salts of alkylsulfuric esters, sulfuric esters of polyoxyethylene alkylethers, salts of sulfuric esters of aliphatic monoglucerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrene-maleic anhydride copolymers, partially saponified compounds of olefin-maleic anhdyride copolymers, and naphthalenesulfonateformalin condensates. Alkyldiphenyloxide disulfonates (such as sodium dodecyl phenoxy benzene disulfonates), alkylated naphthalene sulfonic acids, sulfonated alkyl diphenyl oxides, and methylene dinaphthalene sulfonic acids) are particularly useful as the primary or “first” anionic surfactant. Several commercial examples are described in the Examples below. Such surfactants can be obtained from various suppliers as described in McCutcheon's Emulsifiers & Detergents, 2007 Edition.

Particular examples of such surfactants include but are not limited to, sodium dodecylphenoxyoxybenzene disulfonate, the sodium salt of alkylated naphthalenesulfonate, disodium methylene-dinaphthalene disulfonate, sodium dodecylbenzenesulfonate, sulfonated alkyl-diphenyloxide, ammonium or potassium perfluoroalkylsulfonate and sodium dioctylsulfosuccinate.

The one or more anionic surfactants are generally present in an amount of at least 1 weight %, and typically from about 1 to about 45 weight %, or from about 2 to about 30 weight % (based on the weight of the gum).

Two or more anionic surfactants (“first”, “second”, etc.) can be used in combination. In such mixtures, a first anionic surfactant, such as an alkyldiphenyloxide disulfonate, can be present generally in an amount of at least 1 weight % and typically from about 1 to about 20 weight %. A second surfactant can be present (same or different from the first anionic surfactant) in a total amount of at least 0.1 weight %, and typically from about 1 to about 20 weight %. Second or additional anionic surfactants can be selected from the substituted aromatic alkali alkyl sulfonates and aliphatic alkali sulfates. One particular combination of anionic surfactants includes one or more alkyldiphenyloxide disulfonates and one or more aromatic alkali alkyl sulfonates (such as an alkali alkyl naphthalene sulfonate).

The gums useful in this invention may include nonionic surfactants as described in [0029] or hydrophilic polymers described in [0024] of EP 1,751,625 (noted above), incorporated herein by reference. Particularly useful nonionic surfactants include Mazol® PG031-K (a triglycerol monooleate, Tween® 80 (a sorbitan derivative), Pluronic® L62LF (a block copolymer of propylene oxide and ethylene oxide), and Zonyl® FSN (a fluorocarbon), and a nonionic surfactant for successfully coating the gum onto the printing plate surface, such as a nonionic polyglycol. These nonionic surfactants can be present in an amount of up to 10 weight %, but at usually less than 2 weight %.

Other optional components of the gum include inorganic salts (such as those described in [0032] of U.S. Patent Application 2005/0266349, noted above), wetting agents (such as a glycol), a metal chelating agents, antiseptic agents, anti-foaming agents, ink receptivity agents (such as those described in [0038] of US '349), and viscosity increasing agents as noted above. The amounts of such components are known in the art. Calcium ion chelating agents are particularly useful, including but not limited to, polyaminopoly-carboxylic acids, aminopolycarboxylic acids, or salts thereof, [such as salts of ethylenediaminetetraacetic acid (EDTA, sodium salt)], organic phosphonic acids and salts thereof, and phosphonoalkanetricarboxylic acids and salts thereof. Organic amines may also be useful. A chelating agent may be present in the gum in an amount of from about 0.001 to about 1 weight %.

Generally, the gum is applied to the imaged element by rubbing, spraying, jetting, dipping, coating, or wiping the outer layer with the gum or a roller, impregnated pad, or applicator containing the gum. For example, the imaged element can be brushed with the gum, or the gum may be poured on or applied by spraying the outer layer with sufficient force to remove the exposed regions using a spray nozzle system as described for example in [0124] of EP 1,788,431A2 (noted above). Still again, the imaged element can be immersed in the gum and rubbed by hand or with an apparatus.

The gum can also be applied in a gumming unit (or gumming station) that has at least one roller for rubbing or brushing the printing plate while the gum is applied during development. By using such a gumming unit, the non-exposed regions of the imaged layer may be removed from the substrate more completely and quickly. The gum used in development can be collected in a tank and the gum can be used several times, and replenished if necessary from a reservoir of gum. The gum replenisher can be of the same concentration as that used in development, or be provided in concentrated form and diluted with water at an appropriate time.

Following off-press development, a postbake operation can be carried out, with or without a blanket or floodwise exposure to UV or visible radiation. Alternatively, a blanket UV or visible radiation exposure can be carried out, without a postbake operation.

Printing can be carried out by applying a lithographic printing ink and fountain solution to the printing surface of the imaged and developed element. The fountain solution is taken up by the non-imaged regions, that is, the surface of the hydrophilic substrate revealed by the imaging and development steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

The following examples are provided to illustrate the practice of the invention but are by no means intended to limit the invention in any manner.

### EXAMPLES

Unless otherwise noted below, the chemical components used in the Examples can be obtained from one or more commercial courses such as Aldrich Chemical Company (Milwaukee, Wis.).

The components and materials used in the examples and analytical methods used in evaluation were as follows:

BLO represents γ-butyrolactone.

Byk® 307 is a polyethoxylated dimethyl polysiloxane copolymer that is available from Byk Chemie (Wallingford, Conn.).

CN2302 is a hyperbranched polyester acrylate oligomer obtained from Sartomer Company, Inc. (Exton, Pa.).

DATDA represents N,N-diallyltartardiamide.

Dowfax® 2A1 is an alkyldiphenyloxide disulfonate that is available from Dow Chemical Company (Midland, Mich.).

Dowfax® 3B2 is also an alkyldiphenyloxide disulfonate that is available from Dow Chemical Company (Midland, Mich.).

Dye A (VP Oxa 1) has following structure:

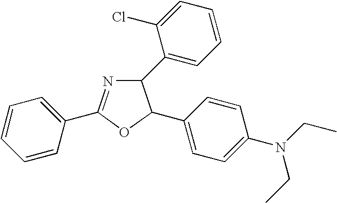

EDTA(Na)₄ salt is ethylenediamine tetraacetic acid, tetra sodium salt hydrate (83.6%).

Graft polymer A is a polymer dispersion containing 20 wt % styrene, 70 wt % acrylonitrile, and 10 wt % polyethylene glycol methyl ether methacrylate, 24% in propanol/water (80/20).

Gum 1 (pH=7.8) was prepared as follows: To 700 g of DI water, 77.3 ml of Dowfax® 3B2 anionic surfactant, 32.6 g of trisodium citrate dehydrate, and 9.8 g of citric acid were added under stirring, and the DI water was further added to bring the total weight of 1,000 g. Trisodium phosphate (25 g) was added to adjust the pH to 7.8.

Gum 2 (pH ˜9.4) is a solution containing 980 g of MX 1591 and 20 g of EDTA(Na)₄ salt.

Initiator A (o-Cl-HABI): 2,2-bis-(-2-chlorophenyl)-4,4′,5,5′-tetraphenyl-biimidazole.

MEK represents methyl ethyl ketone.

MX 1591 is a pre-bake gum (pH=4.2) that is available from Eastman Kodak Company (Rochester, N.Y.).

P/F represents an aluminum substrate post-treatment with an inorganic monosodium phosphate solution activated by sodium fluoride.

PGME represents 1-methoxy-2-propanol and it is also known as Dowanol PM.

Pigment A is a 27% solids dispersion of 7.7 parts of a polyvinyl acetal derived from poly(vinyl alcohol) acetalized with acetaldehyde, butyraldehyde, and 4-formylbenzoic acid, 76.9 parts of Irgalith Blue GLVO (Cu-phthalocyanine C.I. Pigment Blue 15:4) and 15.4 parts of Disperbyk® 167 dispersant (Byk Chemie) in 1-methoxy-2-propanol.

Sartomer 399 is dipentaerythritol pentaacrylate that was obtained from Sartomer Company, Inc. (Exton, Pa.).

Sipomer PAM100 is an ethylene glycol methacrylate phosphate with 4-5 ethylene glycol units that was obtained from Rhodia Inc. (Cranbury, N.J.).

### Synthetic Preparation of Polymer A (Invention):

AIBN [2,2′-azobis(iso-butyronitrile), Vazo-64, 0.8 g], methyl methacrylate (10 g), acrylonitrile (10 g), N-vinyl carbazole (4 g, from Polymer Dajac), methacrylic acid (12 g), PEGMA (8 g), and DMAC (160 g) were placed in a 1000-ml 3-necked flask, equipped with magnetic stirring, temperature controller, and N₂ inlet. The reaction mixture was heated to 75° C. and stirred under N₂ protection overnight (about 16 hours). The % N.V. was measured with about 20%.

To above reaction mixture (after nitrogen protection was removed and temperature was reduced to 55° C.), potassium hydroxide (3.7 g) in water (20 g) was slowly added and a viscous liquid was formed. After stirring the mixture for 20 minutes, allyl bromide (8.0 g) was added and the mixture was stirred at 55° C. for 3 hours. Concentrated (36%) hydrochloric acid (7 g) in DMAC (25 g) was added to the flask and the reaction mixture was stirred for another 3 hours. The resulting reaction mixture was then slowly dropped into a mixture of 6 liters of ice water with 10 g of concentrated hydrochloric acid while stirring. The resulting precipitate was filtered and a fine white powder was obtained after filtration. The powder was dried at room temperature overnight and then at 50° C. for 3 hours to obtain 39 g of polymer solid.

### Synthetic Preparation of Polymer B (Invention):

AIBN [2,2′-azobis(iso-butyronitrile), Vazo-64, 0.8 g], methyl methacrylate (5 g), acrylonitrile (15 g), N-vinyl carbazole (4 g, from Polymer Dajac), methacrylic acid (12 g), PEGMA (8 g), and DMAC (160 g) were placed in a 1000-ml 3-necked flask, equipped with magnetic stirring, temperature controller, and N₂ inlet. The reaction mixture was heated to 75° C. and stirred under N₂ protection overnight (about 16 hours). The % N.V. was measured with about 20%.

To above reaction mixture (after nitrogen protection was removed and temperature was reduced to 55° C.), potassium hydroxide (3.7 g) in water (20 g) was slowly added and a viscous liquid was formed. After stirring the mixture for 20 minutes, allyl bromide (8.0 g) was added and the mixture was stirred at 55° C. for 3 hours. Concentrated (36%) hydrochloric acid (7 g) in DMAC (25 g) was added to the flask and the reaction mixture was stirred for another 3 hours. The resulting reaction mixture was then slowly dropped into a mixture of 6 liters of ice water with 10 g of concentrated hydrochloric acid while stirring. The resulting precipitate was filtered and a fine white powder was obtained after filtration. The powder was dried at room temperature overnight and then at 50° C. for 3 hours to obtain 36 g of polymer solid.

### Invention Example 1

### Preparation of Imageable Element Using Polymer A

An imageable layer formulation was prepared according to this invention by dissolving Polymer A (1.27 g), CN2302 (0.89 g), Dye A (0.63 g), Graft Polymer A (5.39 g), SR-399 (2.30 g, 40% in MEK), Pigment 951 (2.22 g, 10% in PGME), Sipomer PAM100 (0.13 g), Byk® 307 (0.32 g, 10% in PGME), 3-mercaptotriazole (0.38 g), DATDA (0.38 g), and Initiator A (0.22 g) in PGME (31.1 g), water (9.4 g), BLO (7.5 g), and MEK (38.0 g). An electrochemically-grained and sulfuric acid-anodized aluminum substrate that had been post-treated with P/F was coated with the imageable layer formulation at a dry coating weight of about 1.2 g/m² when properly dried at 210° F. (˜99° C.) for about 2 minutes on a rotating drum.

The resulting imageable elements were imaged at a series of exposures (35-184 μJ/cm²) on a Luxel Vx-9600 violet platesetter and processed (developed) in a tray charged with Gum 1 solution diluted with water (Gum 1:water ratio of 1:10) for 8 seconds at 22° C. Uniform image densities [OD=0.50/0.59 (processed/raw)] were obtained for exposures ranging from 160-184 μJ/cm². Another imaged element was processed in a tray charged with Gum 2 solution diluted with water (Gum 2: water ratio of 1:3) for 8 seconds at 22° C. A weak image density [OD=0.32/0.59 (processed/raw)] was obtained for the exposure at 184 μJ/cm².

### Invention Example 2

### Preparation of Imageable Element Using Polymer B

An imageable layer formulation was prepared according to this invention by dissolving Polymer B (1.27 g), CN2302 (0.89 g), Dye A (0.63 g), Graft Polymer A (5.39 g), SR-399 (2.30 g, 40% in MEK), Pigment 951 (2.22 g, 10% in PGME), Sipomer PAM100 (0.13 g), Byk® 307 (0.32 g, 10% in PGME), 3-mercaptotriazole (0.38 g), DATDA (0.38 g), and Initiator A (0.22 g) in PGME (31.1 g), water (9.4 g), BLO (7.5 g), and MEK (38.0 g). An electrochemically-grained and sulfuric acid-anodized aluminum substrate that had been post-treated with P/F was coated with the imageable layer formulation at a dry coating weight of about 1.2 g/m² when properly dried at 210° F. (99° C.) for about 2 minutes on a rotating drum.

The resulting imageable elements were imaged at a series of exposures (35-184 μJ/cm²) on a Luxel Vx-9600 violet platesetter and processed (developed) in a tray charged with Gum 1 solution diluted with water (Gum 1: water ratio of 1:10) for 8 seconds at 22° C. Uniform image densities [OD=0.56/0.62 (processed/raw)] were obtained for exposures ranging from 150-184 μJ/cm². Another imaged element was processed in a tray charged with Gum 2 solution diluted with water (Gum 2: water ratio of 1:3) for 8 seconds at 22° C. Uniform image densities [OD=0.56/0.62 (processed/raw)] were also obtained for exposures ranging from 160-184 μJ/cm².

### Comparative Example 1

### Preparation of Imageable Element Using Polymer B Without an Additive of Structure (I)

An imageable layer formulation outside of the present invention was prepared by dissolving Polymer B (1.27 g), CN2302 (0.89 g), Dye A (0.63 g), Graft Polymer A (5.39 g), SR-399 (2.30 g, 40% in MEK), Pigment 951 (2.22 g, 10% in PGME), Sipomer PAM100 (0.13 g), Byk® 307 (0.32 g, 10% in PGME), 3-mercaptotriazole (0.38 g), poly(ethylene glycol) (0.50 g, MW=800), and Initiator A (0.22 g) in PGME (31.1 g), water (9.4 g), BLO (7.5 g), and MEK (38.0 g). An electrochemically-grained and sulfuric acid-anodized aluminum substrate that had been post-treated with P/F was coated with the imageable layer formulation at a dry coating weight of about 1.2 g/m² when properly dried at 210° F. (˜99° C.) for about 2 minutes on a rotating drum.

The resulting comparative imageable elements were imaged at a series of exposures (35-184 μJ/cm²) on a Luxel Vx-9600 violet platesetter and processed in a tray charged with Gum 2 solution diluted with water (Gum 2: water ratio of 1:3) for 8 seconds at 22° C. No imaging was obtained for the exposures up to 184 μJ/cm².

The invention has been described in detail with particular reference to certain preferred embodiments thereof, but it will be understood that variations and modifications can be effected within the spirit and scope of the invention.

1. A method of providing an image comprising:
A) using a laser providing violet radiation, imagewise exposing a negative-working imageable element comprising a substrate having thereon an outermost negative-working imageable layer to provide exposed and non-exposed regions,
said outermost negative-working imageable layer comprising:
a free radically polymerizable component,
an initiator composition capable of generating free radicals sufficient to initiate polymerization of free radically polymerizable groups upon exposure to imaging violet radiation,
a sensitizer for violet irradiation,
a primary polymeric binder that is represented by the following Structure (I):
-(A)_{w}-(A′)_{w′}- (I)
wherein A represents recurring units comprising a pendant reactive vinyl group, A′ represents recurring units other than those represented by A, w is from about 1 to about 70 mol %, and w′ is from about 30 to about 99 mol %, and
an additive that is represented by the following Structure (II): 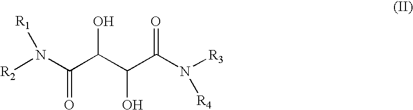
wherein R₁, R₂, R₃, and R₄ are independently hydrogen or alkyl, alkenyl, cycloalkyl, or aryl groups,
B) with or without a post-exposure baking step, contacting said imagewise exposed element with a gum off-press to remove predominantly only said non-exposed regions to provide an image in said developed element, said gum having a pH of from about 6.5 to about 11 and consisting essentially of one or more anionic surfactants in an amount of at least 1 weight %, and does not contain a silicate or metasilicate.

2. (canceled)

3. The method of claim 1 wherein R₁, R₂, R₃, and R₄ are independently alkyl having 1 to 8 carbon atoms, alkenyl having 2 to 6 carbon atoms, phenyl, or naphthyl groups.

4. The method of claim 1 wherein said additive is present in an amount of at least 2 and up to 10 weight %.

5. The method of claim 1 wherein said primary polymeric binder is represented by the following Structure (IA):
-(A)_{w}-(B)ₓ-(C)_{y}-(D)_{z}- (IA)
wherein A represents recurring units derived from a pendant allyl (meth)acrylate or styryl (meth)acrylate group, B represents recurring units comprising pendant cyano groups, C represents recurring units comprising pendant acidic groups, D represents recurring units other than those represented by A, B, and C, w is from about 1 to about 70 mol %, x is from about 10 to about 80 mol %, y is from about 1 to about 30 mol %, and z is from 0 to about 90 mol %.

6. The method of claim 1 wherein said substrate is an aluminum-containing substrate having a hydrophilic surface upon which said imageable layer is disposed.

7. The method of claim 1 wherein said initiator composition comprises a metallocene, azine, peroxide, 2,4,5-triarylimidazolyl dimer, onium salt oxime ester or oxime ether, N-phenyl glycine or a derivative thereof, thiol, or a combination of two or more of these compounds.

8. The method of claim 1 wherein said sensitizer has a spectral sensitivity of from about 350 to about 475 nm,

9. The method of claim 1 wherein said free radically polymerizable component comprises an ethylenically unsaturated free radically polymerizable monomer or oligomer, or free radically crosslinkable polymer.

10. The method of claim 1 wherein said imaged and developed element is a lithographic printing plate.

11. The method of claim 1 wherein said gum has a pH of from about 6.5 to about 10.

12. The method of claim 1 wherein said gum consists essentially of one or more anionic surfactants at least one of which has a sulfonic acid group or salt thereof and is present in said gum in an amount of from about 1 to about 45 weight %.

13. The method of claim 12 wherein at least one of said one or more anionic surfactants is an alkyldiphenyloxide disulfonate that is present in said gum in an amount of from about 2 to about 30 weight %.

14. The method of claim 5 wherein said C recurring units comprise carboxylic acid groups.

15. The method of claim 5 wherein said D recurring units are derived from one or more of vinyl carbazole, methyl (meth)acrylate, poly(ethylene glycol) methyl ether (meth)acrylate, and a styrene monomer.

16. The method of claim 5 wherein said A recurring units are derived from at least allyl (meth)acrylate, said B recurring units are derived from one or more of (meth)acrylonitrile, said C recurring units are derived from one or more of (meth)acrylic acid, 4-carboxyphenyl (meth)acrylate, and 4-carboxystyrene.

17. The method of claim 5 wherein w is from about 5 to about 50 mol %, x is from about 30 to about 70 mol %, y is from about 5 to about 20 mol %, and z is from about 10 to about 60 mol %.

18. The method of claim 1 wherein said gum consists essentially of two or more anionic surfactants at least one of which is an alkyldiphenyloxide disulfonate.

19. The method of claim 18 wherein said gum consists essentially of two or more different anionic surfactants one of which is an alkali alkyl naphthalene sulfonate that is present in an amount of from about 1 to about 20 weight %.

20. The method of claim 1 wherein imagewise exposure is carried out using imaging violet radiation having a λₘₐₓ of from about 390 to about 430 nm,
said free radically polymerizable component is an ethylenically unsaturated free-radical polymerizable monomer, oligomer, or crosslinkable polymer.
said initiator composition comprises a 2,4,5-triarylimidazolyl dimer and a thiol,
said violet sensitizer is a 2,4,5-triaryloxazole derivative,
said polymeric binder is represented by the following Structure (IA):
-(A)_{w}-(B)ₓ-(C)_{y}-(D)_{z}- (IA)
wherein said A recurring units are derived from at least an allyl (meth)acrylate or styryl (meth)acrylate, said B recurring units are derived from one or more of (meth)acrylonitrile, said C recurring units are derived from one or more of (meth)acrylic acid, 4-carboxyphenyl (meth)acrylate, and 4-carboxystyrene, said D recurring units are derived from one or more of vinyl carbazole, methyl (meth)acrylate, poly(ethylene glycol) methyl ether (meth)acrylate, and a styrene monomer, w is from about 5 to about 50 mol %, x is from about 30 to about 70 mol %, y is from about 5 to about 20 mol %, and z is from 10 to about 40 mol %, and
said additive is N,N′-diallyltartardiamide, N,N′-dibenzyltartardiamide, or N,N,N′,N′-tetramethyltartardiamide, or a combination thereof, and is present in an amount of from about 2 to about 10 weight %,
said gum is a pre-bake gum having a pH of from about 6.5 to about 10, and consists essentially of an alkyldiphenyloxide disulfonate in an amount of from about 2 to about 30 weight %, and
said imaged and developed element is a lithographic printing plate having an aluminum-containing hydrophilic substrate.
